(19) United States
(12) Patent Application Publication
(10) Pub. No.: US 2006/0192597 A1
(43) Pub. Date: Aug. 31, 2006

(54) Temperature sensing circuits, and temperature detection circuits including same

(76) Inventors: Charles Ray Johns, Austin, TX (US); Michael Fan Wang, Austin, TX (US); Munehiro Yoshida, Austin, TX (US)

Correspondence Address: IBM CORPORATION (CS);C/O CARR LLP, 670 FOUNDERS SQUARE, 900 JACKSON STREET, DALLAS, TX, 75202, US

(21) Appl. No.: 11/052,495

(22) Filed: Feb. 4, 2005

(51) Int. Cl. H03K 5/22; H03K 5/153

(52) U.S. Cl. 327/77

(57) ABSTRACT

Temperature sensing circuits are disclosed. One embodiment of a temperature sensing circuit includes a voltage divider and an analog multiplexer. The voltage divider network divides an analog voltage into multiple derived analog voltages. The analog multiplexer receives at least two of the derived analog voltages and a control signal, and is configured to produce one of the received derived analog voltages dependent upon the control signal. Temperature detection circuits including the temperature sensing circuits are also disclosed.

### CROSS-REFERENCED APPLICATIONS

This application relates to co-pending U.S. patent applications Ser. No. 10/982,019 entitled “INTEGRATED CIRCUIT DIE INCLUDING A TEMPERATURE DETECTION CIRCUIT, AND SYSTEM AND METHODS FOR CALIBRATING THE TEMPERATURE DETECTION CIRCUIT,” Docket No. AUS920040412US1, filed Nov. 5, 2004, and to “METHOD AND APPARATUS FOR ON-CHIP DYNAMIC TEMPERATURE TRACKING,” Docket No. AUS920041094US1, filed concurrently herewith.

### BACKGROUND OF THE INVENTION

1. Field of the Invention

This invention relates generally to electronic circuits and, more particularly, to temperature sensing and detecting circuits.

2. Description of the Related Art

A wafer fabrication process typically forms many identical integrated circuits upon each of several silicon wafers processed as a group (i.e., lot). Each integrated circuit is formed within a designated area of a wafer, and includes electronic devices electrically coupled by conductive traces called interconnect lines (i.e., interconnects). Interconnects are typically patterned from conductive layers formed on or above the surface of a silicon substrate. Following wafer fabrication, the individual integrated circuit dice are separated from the wafers, and each functional die is typically secured within a protective semiconductor device package.

Integrated circuits dissipate electrical power during operation, transforming electrical energy into heat energy. At the same time, several key operating parameters of an integrated circuit typically vary with temperature, and reliable device operation within specifications occurs only within a defined operating temperature range. For high performance devices, such as microprocessors, specified performance is only achieved when the temperature of the device is below a specified maximum operating temperature. Operation of the device at a temperature above the specified maximum operating temperature, may result in irreversible damage to the device. In addition, it has been established that the reliability of an integrated circuit decreases with increasing operating temperature. The heat energy produced by an integrated circuit during operation must thus be removed from the integrated circuit at a rate which ensures operational and reliability requirements are met.

The continued demand for higher performance microprocessors, aided by advances in integrated circuit fabrication and packaging technologies, has led to higher clock signal frequencies (i.e., increased clock signal speeds) and increased levels of integration. Despite shrinking device sizes, maximum microprocessor power dissipations continue to increase at exponential rates. As a result, it is becoming increasingly more difficult to operate high performance integrated circuits (e.g., microprocessors) such that maximum operating temperatures, specified by manufactures for the operational stability and reliability reasons described above, are not exceeded.

It would thus be beneficial to have a temperature detection circuit for detecting when a temperature exceeds a selected temperature. Such a temperature detection circuit may be, for example, formed on an integrated circuit die and used to keep a temperature of the die below a maximum operating temperature of the integrated circuit.

### SUMMARY OF THE INVENTION

Temperature sensing circuits are disclosed. One embodiment of a temperature sensing circuit includes a voltage divider and an analog multiplexer. The voltage divider network divides an analog voltage into multiple derived analog voltages. The analog multiplexer receives at least two of the derived analog voltages and a control signal, and is configured to produce one of the received derived analog voltages dependent upon the control signal. Temperature detection circuits including the temperature sensing circuits are also disclosed.

### BRIEF DESCRIPTION OF THE DRAWINGS

For a more complete understanding of the present invention and the advantages thereof, reference is now made to the following Detailed Description taken in conjunction with the accompanying drawings, in which:

FIG. 1 is a diagram of one embodiment of a temperature detection circuit including a temperature sensing circuit and a comparator, wherein the temperature sensing circuit produces an analog voltage VD1 and an analog voltage VR2;

FIG. 2 is a graph of the analog voltages VD1 and VR2 produced by the temperature sensing circuit of FIG. 1 versus temperature in an ideal case;

FIG. 3 illustrates variations in the analog voltage VD1 of FIG. 2 that may be expected to occur when the temperature sensing circuit of FIG. 1 is manufactured or fabricated;

FIG. 4 illustrates variations in the analog voltage VR2 of FIG. 2 that may be expected to occur when the temperature sensing circuit of FIG. 1 is manufactured;

FIG. 5 illustrates how ranges of the variations of the analog voltages VD1 (FIG. 3) and VR2 (FIG. 4) result in a range of a temperature detected by the temperature detection circuit of FIG. 1;

FIG. 6 is a graph of the analog voltages VD1 and VR2 produced by the temperature sensing circuit of FIG. 1 versus temperature illustrating an approach to substantially reducing error in the temperature detected by the temperature detection circuit of FIG. 1; and

FIG. 7 is a diagram of a temperature detection circuit wherein an analog voltage produced within a temperature sensing circuit is divided into multiple analog voltages, and a selected one of the multiple analog voltages is used to detect when a temperature of the temperature sensing circuit is above a selected temperature.

### DETAILED DESCRIPTION

In the following discussion, numerous specific details are set forth to provide a thorough understanding of the present invention. However, those skilled in the art will appreciate that the present invention may be practiced without such specific details. In other instances, well-known elements have been illustrated in schematic or block diagram form in order not to obscure the present invention in unnecessary detail. Additionally, for the most part, details concerning network communications, electro-magnetic signaling techniques, and the like, have been omitted inasmuch as such details are not considered necessary to obtain a complete understanding of the present invention, and are considered to be within the understanding of persons of ordinary skill in the relevant art.

It is further noted that, unless indicated otherwise, all functions described herein may be performed in either hardware or software, or some combination thereof. In a preferred embodiment, however, the functions are performed by a processor, such as a computer or an electronic data processor, in accordance with code, such as computer program code, software, and/or integrated circuits that are coded to perform such functions, unless indicated otherwise.

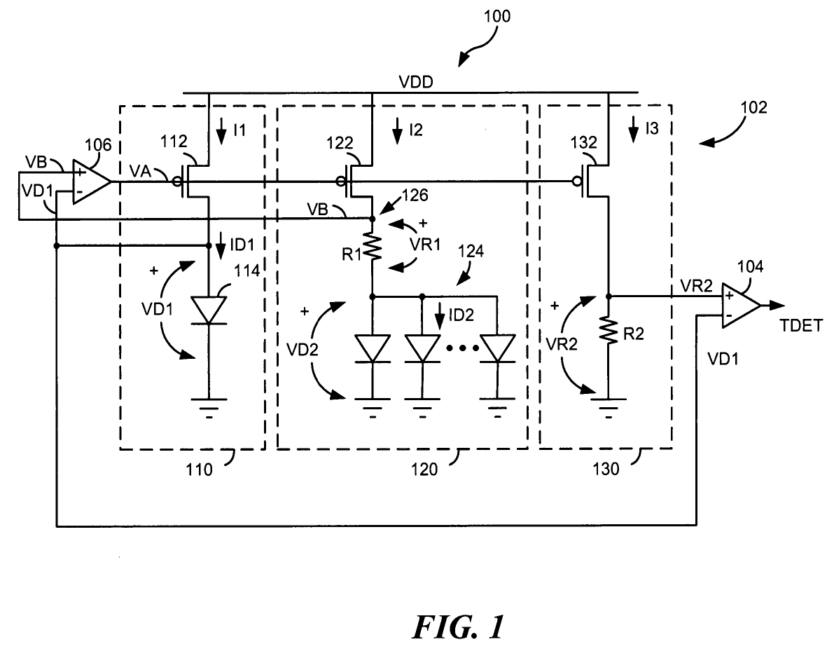

Turning now to FIG. 1, the reference numeral 100 generally indicates a temperature detection circuit including a temperature sensing circuit 102 and a comparator 104. In the embodiment of FIG. 1, the temperature detection circuit 100 uses two analog voltages produced by the temperature sensing circuit 102 to detect a condition wherein a temperature of the temperature sensing circuit 102 is greater than (i.e., above) a selected temperature. As described in detail below, one of the analog voltages has a magnitude that increases with increasing temperature, and the other analog voltage has a magnitude that decreases with increasing temperature.

In one embodiment, the entire temperature detection circuit 100 is formed on and in a surface of a semiconductor substrate of an integrated circuit die or “chip” (e.g., during a wafer fabrication process), and constitutes an “on-chip” thermal detection circuit for detecting when a temperature of the semiconductor substrate is above the selected temperature. The comparator 104 compares the two analog voltages produced by the temperature sensing circuit 102, and produces an output signal “TDET” of the temperature detection circuit 100. In general, the output signal TDET is in one voltage state (e.g., a low voltage state) when the temperature of the semiconductor substrate is below the selected temperature, and in another voltage state (e.g. a high voltage state) when the temperature of the semiconductor substrate is above the selected temperature. Thus the output signal TDET of the temperature detection circuit 100 is basically a digital signal indicative of whether the temperature of the semiconductor substrate is above the selected temperature.

It is noted that in other embodiments at least the temperature sensing circuit 102 of the temperature detection circuit 100 may be formed on or in, or thermally coupled to, a body, and the temperature detection circuit 100 may be used to detect when a temperature of the body is above the selected temperature.

The temperature sensing circuit 102 includes a differential amplifier 106, a first portion 110, a second portion 120, and a third portion 130. The structure of the temperature sensing circuit 102 will first be described, followed by a description of operation.

The first portion 110 includes a p-channel metal oxide semiconductor (PMOS) transistor 112 and a p-n junction element 114 connected in series. A source terminal of the PMOS transistor 112 is connected to a positive power supply voltage “VDD,” and a drain terminal of the PMOS transistor 112 is connected to a p-type terminal of the p-n junction element 114. An n-type terminal of the p-n junction element 114 is connected to a reference ground power supply voltage.

The PMOS transistor 112 receives an output analog voltage “VA” of the differential amplifier 106 at a gate terminal. The analog voltage VA establishes a current I1 through the series connected PMOS transistor 112 and p-n junction element 114. An analog voltage “VD1” is developed across the forward biased p-n junction element 114, and a current ID1 flows through the p-n junction element 114.

The second portion 120 includes a PMOS transistor 122, a resistor labeled “R1,” and m p-n junction elements 124, where m is generally greater than or equal to 2. The m p-n junction elements 124 are connected in parallel. The PMOS transistor 122 is connected in series with the resistor R1 and the m p-n junction elements 124. A source terminal of the PMOS transistor 122 is connected to the positive power supply voltage VDD, and a drain terminal of the PMOS transistor 122 is connected to one terminal of the resistor R1 at a node 126. The other terminal of the resistor R1 is connected to p-type terminals of the m p-n junction elements 124. N-type terminals of the m p-n junction elements 124 are connected to the reference ground power supply voltage. In one embodiment, the number of p-n junction elements 124 is 10 (m=10). The p-n junction element 114 and the m p-n junction elements 124 may be, for example, diodes. Alternately, the p-n junction element 114 and the m p-n junction elements 124 may be diode-connected bipolar transistors.

Like the PMOS transistor 112 of the first portion 110, the PMOS transistor 122 of the second portion 120 receives the output analog voltage VA of the differential amplifier 106 at a gate terminal. The analog voltage VA establishes a current I2 through the PMOS transistor 122, the resistor R1, and the p-n junction elements 124. In the embodiment of FIG. 1, the PMOS transistors 112 and 122 are fabricated similarly, and I2=I1. An analog voltage “VR1” is developed across the resistor R1, where VR1=I2·R1. In general, an analog voltage “VD2” is developed across the m p-n junction elements 124 connected in parallel, and a current ID2 flows through each of the m p-n junction elements 124.

An analog voltage “VB” is developed at the node 126 of the second portion 120, wherein VB=VR1+VD2. The analog voltage VB is provided to a positive “+” terminal of the differential amplifier 106, and the analog voltage VD1 produced by the first portion 110 is provided to a negative “−” terminal of the differential amplifier 106. In general, the output analog voltage VA of the differential amplifier 106 is stable when VB=VD1.

The third portion 130 includes a PMOS transistor 132 and a resistor labeled R2 connected in series. A source terminal of the PMOS transistor 132 is connected to the positive power supply voltage VDD, and a drain terminal of the PMOS transistor 132 is connected to one terminal of the resistor R2. The other terminal of the resistor R2 is connected to the reference ground power supply voltage.

Like the PMOS transistor 112 of the first portion 110 and the PMOS transistor 122 of the second portion 120, the PMOS transistor 132 of the third portion 130 receives the output analog voltage VA of the differential amplifier 106 at a gate terminal. The analog voltage VA establishes a current I3 through the PMOS transistor 132 and the resistor R2. In the embodiment of FIG. 1, the PMOS transistors 112, 122, and 132 are fabricated similarly, and I1=I2=I3. A voltage “VR2” is developed across the resistor R2 where VR2=I3·R2.

In the embodiment of FIG. 1, the differential amplifier 106 and the three PMOS transistors 112, 122, and 132 constitute current control means for controlling currents I1, I2, and I3 such that I1=I2=I3. For example, the differential amplifier 106 may be, or include, an operational amplifier. Other means for controlling currents I1, I2, and I3 such that I1=I2=I3 are also possible.

Regarding the operation of the temperature sensing circuit 102, the p-n junction element 114 of the first portion 110 is forward biased. The relationship between the analog voltage VD1 across the p-n junction element 114 and the current ID1 through the p-n junction element 114 is given by the well know diode equation:
ID1=(Is)·{exp[(VD1)·(q/ηkT)]−1}
where “Is” is the saturation current, “q” is the electron charge, “η” is an empirical constant, “k” is Boltzmann's constant, and “T” is the absolute temperature of the p-n junction element 114 (in degrees Kelvin).

Assuming (VD1)·(q/ηkT) is much greater than 1, VD1 can be estimated as:
VD1=(ηkT/q)·ln(ID1/Is).

Although the absolute temperature T is in the numerator of the above equation for the analog voltage VD1, and might suggest that the analog voltage VD1 increases with increasing absolute temperature T of the p-n junction element 114, it is well-known that the saturation current Is increases with increasing temperature. As a result, the analog voltage VD1 across the p-n junction element 114 decreases linearly with increasing absolute temperature T of the temperature sensing circuit 102. In the embodiment of FIG. 1, the p-n junction element 114 is formed by doping a silicon substrate, and the rate of change of the analog voltage VD1 with temperature is about −2.2 millivolts (mV) per degree Kelvin (or Celsius).

The m p-n junction elements 124 of the second portion 120 are also forward biased, and similar equations apply. It was noted above that I1=I2=I3. Using:
I1=ID1=(Is)·{exp[(VD1)·(q/ηkT)]−1}, and
I2=m·ID2=m·(Is)·{exp[(VD2)·(q/ηkT)]−1},
it can be shown that:
VD1=ln(m)·(ηkT/q)+VD2.

It was also noted above that the output analog voltage VA of the differential amplifier 106 is stable when VB=VD1, and that the analog voltage VB developed at the node 126 of the second portion 120 is given by VB=VR1+VD2. Thus:
VR1=VB−VD2=ln(m)·(ηkT/q).

It is noted that the analog voltage VR1 developed across the resistor R1 in the second portion 120 is directly proportional to the absolute temperature T of the temperature sensing circuit 102, and is dependent upon m, the number of the p-n junction elements 124. That is, VR1 increases linearly with increasing absolute temperature T of the temperature sensing circuit 102, and VR1 increases with increasing m.

In the third portion 130, VR2=I3·R2. It is also true the I3=I2, I2=VR1/R1, and VR1=ln(m)·(ηkT/q). Thus:
VR2=(VR1/R1)·R2=VR1·(R2/R1)=ln(m)·(ηkT/q)·(R2/R1).

It is noted that the analog voltage VR2 produced across the resistor R2 in the third portion 130 is directly proportional to the analog voltage VR1 developed across the resistor R1 in the second portion 120. Thus like the analog voltage VR1, the analog voltage VR2 increases linearly with increasing absolute temperature T of the temperature sensing circuit 102. The values of the resistors R1 and R2 can advantageously be selected to achieve a desired rate of change of the analog voltage VR2 with the absolute temperature T of the temperature sensing circuit 102. Further, in the embodiment of FIG. 1, the resistors R1 and R2 are fabricated in a similar manner. In this situation, the change in the resistance of resistor R1 due to temperature is advantageously canceled by a corresponding change in the resistance of resistor R2 due to temperature.

In the embodiment of FIG. 1, the comparator 104 of the temperature detection circuit 100 receives the analog voltage VR2 produced by the third portion 130 of the temperature sensing circuit 102 at a positive “+” terminal, and the analog voltage VD1 produced by the first portion 110 of the temperature sensing circuit 102 at a negative “−” terminal. In one embodiment, the rate of change of the analog voltage VD1 with temperature is about −2.0 millivolts (mV) per degree Celsius, and the rate of change of the analog voltage VR2 with temperature is about +2.0 mV per degree Kelvin (or Celsius).

The comparator 104 produces the output signal TDET having a low voltage state (e.g., substantially the reference ground power supply voltage) when a magnitude of the analog voltage VD1 is greater than a magnitude of the analog voltage VR2 (i.e., when the temperature of the temperature sensing circuit 102 is less than the selected temperature). The output signal TDET is in a high voltage state (e.g., substantially the positive power supply voltage VDD) when the magnitude of the analog voltage VR2 is greater than the magnitude of the analog voltage VD1 (i.e., the temperature of the temperature sensing circuit 102 is greater than the selected temperature). The output signal TDET is basically a digital signal indicative of whether the temperature of the temperature sensing circuit 102 is above the selected temperature.

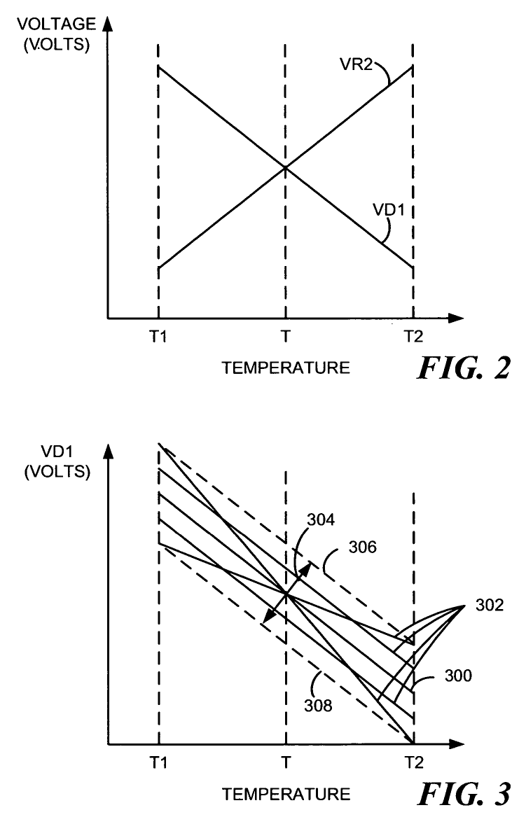

FIGS. 2-5 will now be used to describe a disadvantage of the relatively simple temperature detection circuit 100 of FIG. 1 due mainly to component variations occurring during a manufacturing process. FIG. 2 is a graph of the analog voltages VD1 and VR2 produced by the temperature sensing circuit 102 of FIG. 1 versus temperature in an ideal case. As described above and illustrated in FIG. 2, the analog voltage VD1 developed across the forward-biased p-n junction element 114 of FIG. 1 deceases linearly with increasing temperature. In contrast, the analog voltage VR2 developed across the resistor R2 of FIG. 1 increases linearly with increasing temperature. As described above, in one embodiment, the rate of change of the analog voltage VD1 with temperature is about −2.0 millivolts (mV) per degree Celsius), and the rate of change of the analog voltage VR2 with temperature is about +2.0 mV per degree Celsius.

In the ideal case of FIG. 2, the analog voltage VD1 and the analog voltage VR2 are equal when the temperature of the temperature sensing circuit 102 of FIG. 1 is the selected temperature T. In FIG. 2 the lines representing VD1 and VR2 versus temperature intersect at the selected temperature T. The comparator 104 of the temperature detection circuit 100 of FIG. 1 can thus be easily used to determine when the temperature of the temperature sensing unit 102 is greater than the selected temperature T.

FIG. 3 illustrates variations in the analog voltage VD1 of FIG. 2 that may be expected to occur when the temperature sensing circuit 102 of FIG. 1 is manufactured or fabricated. In FIG. 3, the line representing the magnitude of the analog voltage VD1 versus temperature in the ideal case of FIG. 2 is labeled 300. Due mainly to manufacturing process variations, any one of several other lines labeled 302 may also be achieved. In general, a range 304 encompassing the variations of the analog voltage VD1 can be bounded by a first line 306 representing the magnitude of the analog voltage VD1 plus a maximum positive error quantity “VD1E+,” and a second line 308 representing the magnitude of the analog voltage VD1 minus a maximum negative error quantity “VD1E−.” It is noted that the error quantities VD1E+ and VD1E− are not necessarily equal.

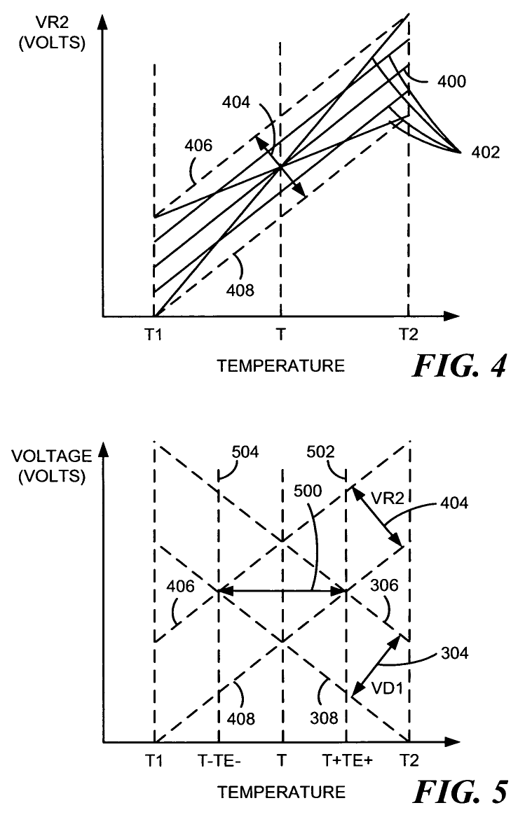

FIG. 4 illustrates variations in the analog voltage VR2 of FIG. 2 that may be expected to occur when the temperature sensing circuit 102 of FIG. 1 is manufactured. In FIG. 4, the line representing the magnitude of the analog voltage VR2 versus temperature in the ideal case of FIG. 2 is labeled 400. Due mainly to manufacturing process variations, any one of several other lines labeled 402 may also be achieved. In general, a range 404 encompassing the variations of the analog voltage VR2 can be bounded by a first line 406 representing the magnitude of the analog voltage VR2 plus a maximum positive error quantity “VR2E+,” and a second line 408 representing the magnitude of the analog voltage VR2 minus a maximum negative error quantity “VR2E−.” It is noted that the error quantities VR2E+ and VR2E− are not necessarily equal. Further, the error quantities VR2E+ and VD1E+ described above are not necessarily equal, and the error quantities VR2E− and VD1E− described above are not necessarily equal.

FIG. 5 illustrates how the ranges 304 (FIG. 3) and 404 (FIG. 4) of the respective analog voltages VD1 and VR2 result in a range 500 of the temperature T detected by the temperature detection circuit 100 of FIG. 1. As described above an illustrated in FIG. 5, the range 304 encompassing the variations of the analog voltage VD1 is bounded by the lines 306 and 308 (see FIG. 3), and the range 404 encompassing the variations of the analog voltage VR2 is bounded by the lines 406 and 408 (see FIG. 4). The variations in the analog voltages VD1 and VR2 produce the range 500 encompassing variations in the temperature T detected by the temperature detection circuit 100 of FIG. 1. As illustrated in FIG. 5, the range 500 is bounded by a first line 502 representing the selected temperature T plus a maximum positive error quantity “TE+,” and a second line 504 representing the selected temperature T minus a maximum negative error quantity “TE−.” It is noted that the error quantities TE+ and TE− are not necessarily equal. In one particular situation, it was determined that the magnitudes of TE+ and TE− might be as large as 30 degrees Centigrade (deg. C.).

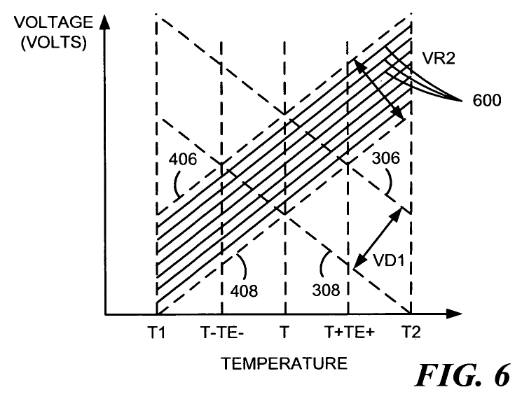

FIG. 6 is a graph of the analog voltages VD1 and VR2 produced by the temperature sensing circuit 102 of FIG. 1 versus temperature illustrating an approach to substantially reducing error in the temperature T detected by the temperature detection circuit 100 of FIG. 1. In the approach of FIG. 6, a detection temperature T (deg. C.) and a desired accuracy (deg. C.) are selected. The error quantities TE+ and TE− for the temperature detection circuit 100 are determined (e.g., by estimation or experimentation). The value of the resistor R2 of the temperature sensing circuit 102 is then selected such that the temperature detection circuit 100 ideally detects a temperature of [T−(TE−)]. The analog voltage VR2 produced by the temperature sensing circuit 102 is then divided (e.g., via a voltage divider network) to form multiple analog voltages labeled 600 in FIG. 6. In general, the number of the multiple analog voltages 600 is sufficient to achieve the desired accuracy.

After fabrication of the temperature detection circuit 100 of FIG. 1, a particular one of the multiple analog voltages 600 is selected (e.g., during a calibration procedure) such that the temperature detection circuit 100 detects the selected temperature T plus or minus a value that is less than or equal to the desired accuracy in degrees.

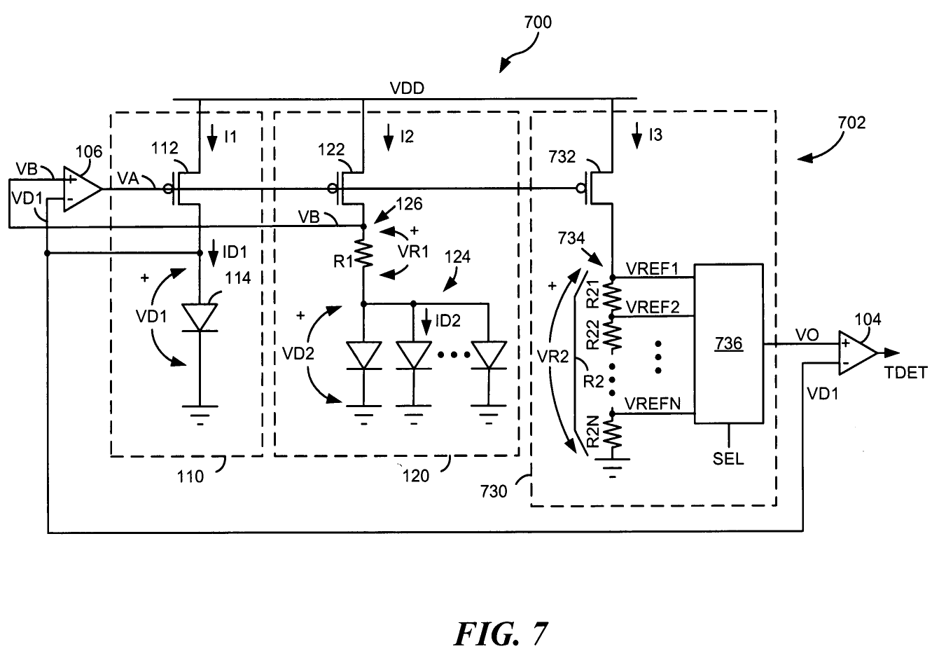

FIG. 7 is a diagram of a temperature detection circuit 700 wherein an analog voltage produced within a temperature sensing circuit 702 is divided into multiple analog voltages, and a selected one of the multiple analog voltages is used to detect when a temperature of the temperature sensing circuit 702 is above a selected temperature. Elements of the temperature detection circuit 700 shown in FIG. 1 and described above are labeled similarly in FIG. 7.

Like the temperature detection circuit 100 of FIG. 1, the temperature detection circuit 700 uses two analog voltages produced by a temperature sensing circuit to detect a condition wherein a temperature of the temperature sensing circuit is above a selected temperature. One of the analog voltages has a magnitude that increases with increasing temperature, and the other analog voltage has a magnitude that decreases with increasing temperature.

In one embodiment, the entire temperature detection circuit 700 is formed on (and in) a surface of a semiconductor substrate of an integrated circuit die or chip (e.g., during a wafer fabrication process), and constitutes an on-chip thermal detection circuit for detecting when a temperature of the semiconductor substrate is above the selected temperature. The comparator 104 compares the two analog voltages produced by the temperature sensing circuit 702, and produces the output signal TDET such that the output signal TDET is in one voltage state (e.g., a low voltage state) when the temperature of the semiconductor substrate is below the selected temperature, and in another voltage state (e.g. a high voltage state) when the temperature of the semiconductor substrate is above the selected temperature. Thus the output signal TDET of the temperature detection circuit 700 is basically a digital signal indicative of whether the temperature of the semiconductor substrate is above the selected temperature.

It is noted that in other embodiments at least the temperature sensing circuit 702 of the temperature detection circuit 700 may be formed in, or thermally coupled to, a body, and the temperature detection circuit 700 may be used to detect when a temperature of the body is above the selected temperature.

The temperature sensing circuit 702 includes the differential amplifier 106, the first portion 110, the second portion 120, and a third portion 730. The structures and operations of the first portion 110 and the second portion 120 are described above.

In the embodiment of FIG. 7, the third portion 730 includes a PMOS transistor 732 and a voltage divider network 734 connected in series. The voltage divider network 734 includes n resistors connected in series and labeled “R21,” “R22,” . . . “R2n” in FIG. 7. In general, n is greater than or equal to 2. A total resistance of the voltage divider network 734 is made equal to the resistance of the resistor R2 of FIG. 1 purely for convenience. A source terminal of the PMOS transistor 732 is connected to the positive power supply voltage VDD, and a drain terminal of the PMOS transistor 732 is connected to one terminal of the resistor R21 of the voltage divider network 734. A terminal of the resistor R2n of the voltage divider network 734 is connected to the reference ground power supply voltage.

Like the PMOS transistor 112 of the first portion 110 and the PMOS transistor 122 of the second portion 120, the PMOS transistor 732 of the third portion 730 receives the output analog voltage VA of the differential amplifier 106 at a gate terminal. The analog voltage VA establishes a current I3 through the PMOS transistor 732 and the n resistors of the voltage divider network 734. In the embodiment of FIG. 7, the PMOS transistors 112, 122, and 732 are fabricated similarly, and I1=I2=I3. As described above, the total resistance of the voltage divider network 734 is equal to R2, the resistance of the resistor R2 of FIG. 1, and the analog voltage VR2 is developed across the voltage divider network 734.

The voltage divider network 734 divides the analog voltage VR2 into n analog voltages signals “VREF1,” “VREF2,” . . . “VREFn.” The analog voltage signal VREF1 is produced at a node where the drain terminal of the PMOS transistor 732 is connected to the terminal of the resistor R21 of the voltage divider network 734, and VREF1=VR2. The analog voltage signal VREF2 is produced at a node between the other terminal of the resistor R21 and a terminal of the resistor R22 of the voltage divider network 734. The analog voltage signal VREFn is produced at a node between a terminal of a resistor R2(n-1) and a terminal of the resistor R2n.

In one embodiment, the resistances of the resistors R21, R22, . . . , R2n are substantially equal, and an analog voltage VREFk produced by the voltage divider network 734 is substantially equal to VR2·[(n−k−1)/n] where k is between 1 and n. In other embodiments the resistors R21, R22, . . . , R2n may have different values. In one particular embodiment, the resistances of the resistors R21, R22, . . . , R2(n-1) are substantially equal, and the resistor R2n is a base resistor having a value that differs from the other resistors.

In the embodiment of FIG. 7, the differential amplifier 106 and the three PMOS transistors 112, 122, and 732 constitute current control means for controlling currents I1, I2, and I3 such that I1=I2=I3. For example, the differential amplifier 106 may be, or include, an operational amplifier. Other means for controlling currents I1, I2, and I3 such that I1=I2=I3 are also possible.

In the embodiment of FIG. 7, the third portion 730 also includes an analog multiplexer 736. In general, the analog multiplexer 736 receives the n analog voltages signals produced by the voltage divider network 734 at data input terminals, and a control signal “SEL” at a control terminal or port. The analog multiplexer 736 produces one of the n analog voltages dependent upon the SEL control signal. The third portion 730 produces the one of the n analog voltages produced by the analog multiplexer 736 as an output analog voltage “VO.”

Again, as the total resistance of the voltage divider network 734 is R2, the analog voltage VR2 developed across the voltage divider network 734 is given by VR2=I3·R2. It is also true the I3=I2, I2=VR1/R1, and VR1=ln(m)·(ηkT/q). Thus:
VR2−(VR1/R1)·R2=VR1·(R2/R1)=ln(m)·(ηkT/q)·(R2/R1).
Accordingly, in the embodiment where the resistances of the resistors R21, R22, . . . , R2n are substantially equal, the analog voltage signal VREFk produced by the voltage divider network 734 is substantially equal to ln(m)·(ηkT/q)·[(n−k−1)/n] where k is between 1.

It is noted that the values of the resistor R1 and the total resistance R2 of the voltage divider network 734 can advantageously be selected to achieve a desired rate of change of the analog voltage VR2 with the absolute temperature T of the temperature sensing circuit 702. Further, in the embodiment of FIG. 7, the resistors R1 and R21, R22, . . . , R2n of the voltage divider network 734 are fabricated in a similar manner. In this situation, the change in the resistance of resistor R1 due to temperature is advantageously canceled by corresponding changes in the resistors R1 and R21, R22, . . . , R2n of the voltage divider network 734 due to temperature.

In the embodiment of FIG. 7, the comparator 104 of the temperature detection circuit 700 receives the output analog voltage VO produced by the third portion 730 of the temperature sensing circuit 702 at a positive “+” terminal, and the analog voltage VD1 produced by the first portion 110 of the temperature sensing circuit 702 at a negative “−” terminal. The comparator 104 produces the output signal TDET having a low voltage state (e.g., substantially the reference ground power supply voltage) when a magnitude of the analog voltage VD1 is greater than a magnitude of the analog voltage VO (i.e., when the temperature of the temperature sensing circuit 702 is less than the selected temperature). The output signal TDET is in a high voltage state (e.g., substantially the positive power supply voltage VDD) when the magnitude of the analog voltage VO is greater than the magnitude of the analog voltage VD1 (i.e., the temperature of the temperature sensing circuit 702 is greater than the selected temperature). The output signal TDET is basically a digital signal indicative of whether the temperature of the temperature sensing circuit 702 is above the selected temperature.

In one embodiment, the SEL control signal provided to the analog multiplexer 736 is a digital signal including int[log₂(n)] bits, wherein the “int” operation returns the smallest integer “i” wherein 2ⁱ is greater than or equal to n. The bit(s) of the SEL control signal are ordered, and specify a corresponding value. In general, the SEL control signal has a corresponding value between 0 and 2ⁱ−1. For example, a 4-bit SEL control signal may be denoted “SEL<0:3>,” where bit SEL<0> is the most significant bit, and SEL<3> is the least significant bit. The corresponding value of the SEL<0:3> control signal is: (SEL<0>)·2³+(SEL<1>)·2²+(SEL<2>)·2¹+(SEL<3>). Thus the 4-bit SEL control signal SEL<0:3> specifies a value between 0 and 15.

During the design of the temperature detection circuit 700 of FIG. 7, a detection temperature T (deg. C.) and a desired accuracy (deg. C.) are selected. The error quantities TE+ and TE− for the temperature detection circuit 700 are determined (e.g., by estimation or experimentation). The total resistance R2 of the voltage divider network 734 is selected such that the analog voltage VR2 developed across the voltage divider network 734 ideally detects a temperature [T−(TE−)]. The number n of the resistors of the voltage divider network 734 is determined using:
n={[(TE+)+(TE−)]/(desired accuracy)−1}.

For example, assume the temperature detection circuit 700 of FIG. 7 is to be designed for a detection temperature T of 85 deg. C. and a desired accuracy of ±2 deg. C. Also assume error quantities TE+ and TE− of 16 deg. C. and 14 deg. C., respectively, are determined for a technology and manufacturing process to be used to fabricate the temperature detection circuit 700. The total resistance R2 of the voltage divider network 734 is selected such that the analog voltage VR2 developed across the voltage divider network 734 ideally detects a temperature [T−(TE−)]=(85−14)=71 deg. C. The number n of the resistors of the voltage divider network 734 is determined as:
n={[(16)+(14)]/(2)−1}=14.

The SEL control signal is to have i bits, where:
i=int[log₂(14)]=4.

After fabrication of the temperature detection circuit 700 of FIG. 7, the bits of the SEL control signal (i.e., the value of the SEL control signal) provided to the analog multiplexer 736 can be selected such that the temperature detection circuit 700 detects the selected temperature T plus or minus a value that is less than or equal to the desired accuracy in degrees.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Many such variations and modifications may be considered desirable by those skilled in the art based upon a review of the foregoing description of preferred embodiments. Accordingly, it is appropriate that the appended claims be construed broadly and in a manner consistent with the scope of the invention.

1. A temperature sensing circuit, comprising:
a voltage divider network configured to divide an analog voltage into a plurality of derived analog voltages; and
an analog multiplexer coupled to receive at least two of the derived analog voltages and a control signal, and configured to produce one of the received derived analog voltages dependent upon the control signal.

2. The temperature sensing circuit as recited in claim 1, wherein the analog voltage has a magnitude that increases with increasing temperature, and varies substantially linearly with temperature.

3. The temperature sensing circuit as recited in claim 1, wherein each of the derived analog voltages has a magnitude that increases with increasing temperature.

4. The temperature sensing circuit as recited in claim 1, wherein the voltage divider network comprises a plurality of resistors connected in series, and wherein all but one of the analog voltages is produced at a node between two adjacent resistors of the voltage divider network.

5. A temperature sensing circuit, comprising:
a first portion comprising a p-n junction element and generating a first analog voltage VD1 across the p-n junction element, wherein the analog voltage VD1 has a magnitude that decreases with increasing temperature;
a second portion comprising a resistance R1 and generating an analog voltage VR1 across the resistor, wherein the analog voltage VR1 has a magnitude that increases with increasing temperature;
a third portion comprising a voltage divider network and generating an analog voltage VR2 across the voltage divider network, wherein the analog voltage VR2 has a magnitude that increases with increasing temperature, and wherein the voltage divider network divides the analog voltage VR2 into a plurality of analog voltages; and
an analog multiplexer coupled to receive each of the analog voltages produced by the voltage divider network and a control signal, and configured to produce one of the analog voltages dependent upon the control signal.

6. The temperature sensing circuit as recited in claim 5, wherein the analog voltage VR2 is substantially equal to VR1·(R2/R1).

7. The temperature sensing circuit as recited in claim 5, wherein the analog voltage VD1 has a magnitude that varies substantially linearly with temperature, and varies substantially linearly with temperature.

8. The temperature sensing circuit as recited in claim 5, wherein each of the analog voltages produced by the voltage divider network has a magnitude that increases with increasing temperature.

9. The temperature sensing circuit as recited in claim 5, wherein the voltage divider network comprises n resistors connected in series, wherein n is greater than or equal to 2, and wherein the voltage divider network produces n analog voltages.

10. The temperature sensing circuit as recited in claim 9, wherein the n resistors have substantially equal resistance values.

11. The temperature sensing circuit as recited in claim 9, wherein a kth one of the n analog voltages is substantially equal to VR1·(R2/R1)·[(n−k−1)/n] where k is between 1 and n.

12. The temperature sensing circuit as recited in claim 9, wherein all but one of the n resistors have substantially equal resistance values.

13. The temperature sensing circuit as recited in claim 5, wherein the second portion comprises m p-n junction elements connected in parallel, and wherein the m p-n junction elements are connected in series with the resistance R1.

14. The temperature sensing circuit as recited in claim 13, wherein the analog voltage VR1 has a magnitude dependent upon m, and wherein the second portion generates an analog voltage VB across the resistance R1 and the m p-n junction elements.

15. The temperature sensing circuit as recited in claim 5, further comprising current control means for controlling a current I1 through the p-n junction element of the first section, a current I2 through the resistance R1 of the second portion, and a current I3 through the voltage divider network of the third portion such that the current I1, the current I2, and the current I3 are equal.

16. A temperature detection circuit, comprising:
a temperature sensing circuit coupled to receive a select signal and configured to produce a plurality of analog voltages, to select one of the analog voltages dependent upon the select signal, and to provide the selected analog voltage as a first analog voltage; and
a comparator coupled to receive the first analog voltage and configured to produce an output signal dependent upon the first analog voltage, wherein the output signal is indicative of whether a temperature of the temperature sensing circuit is greater than a selected temperature.

17. The temperature detection circuit as recited in claim 16, wherein the select signal is a n-bit digital signal, wherein n is an integer greater than or equal to 1.

18. The temperature detection circuit as recited in claim 16, wherein the temperature sensing circuit comprises a voltage divider network configured to produce the plurality of analog voltages.

19. The temperature detection circuit as recited in claim 16, wherein the temperature sensing circuit comprises an analog multiplexer coupled to receive each of the plurality of analog voltages and the select signal, and configured to select one of plurality of analog voltages dependent upon the select signal.

20. The temperature detection circuit as recited in claim 16, wherein the temperature sensing circuit is configured to produce a second analog voltage, and wherein the comparator is coupled to receive the first analog voltage at one input and the second analog voltage at another input, and configured to generate the output signal dependent upon the relative magnitudes of the first analog voltage and the second analog voltage.
